(19) United States
(12) Patent Application Publication
(10) Pub. No.: US 2010/0078191 A1
(43) Pub. Date: Apr. 1, 2010

(54) HERMETIC SEAL AND A METHOD OF MANUFACTURING HERMETIC SEAL

(75) Inventors: Chise NANBA, Tokyo (JP); Akira NAKAMURA, Tokyo (JP); Toru YOSHIHARA, Tokyo (JP)

Correspondence Address: BUCHANAN, INGERSOLL & ROONEY PC, POST OFFICE BOX 1404, ALEXANDRIA, VA, 22313-1404, US

(73) Assignee: MITSUBISHI ELECTRIC CORPORATION, Chiyoda-ku (JP)

(21) Appl. No.: 12/566,727

(22) Filed: Sep. 25, 2009

(30) Foreign Application Priority Data
Sep. 30, 2008 (JP) 2008-253193

(51) Int. Cl. H05K 5/06

(52) U.S. Cl. 174/50.61

(57) ABSTRACT

A hermetic seal includes a package base, a glass material provided on the inside of the package base, and a lead pin that is provided to penetrate through the glass material and is composed of a copper-tungsten alloy.

### BACKGROUND OF THE INVENTION

1. Field of the Invention

The present invention relates to a hermetic seal for a package that hermetically seals an element which is required to operate stably and in which a large current flows.

2. Description of the Related Art

An element such as a semiconductor element that is required to operate stably, particularly an optical semiconductor element, is often packaged in a hermetically sealed manner to suppress degradation of a property such as fluctuation of an output signal due to the exterior environment. An iron-nickel alloy is often used for a conventional hermetic seal package; however, it is also known that a lead pin is composed of nonmagnetic nickel-molybdenum alloy, nickel-chrome-molybdenum alloy, stainless steel, or the like for improving corrosion resistance, which is disclosed, for example, in Japanese Patent Application Laid-open No. 2005-353291.

However, in a case where the lead pin is composed of a nonmagnetic material such as a nickel-molybdenum alloy, a nickel-chrome-molybdenum alloy, and a stainless steel, the resistivity of the material is about 10×10⁻⁷ Ωm, which is not sufficiently low. Therefore, for example, if a large current of about 5 amperes (A) on the average flows in the lead pin having a diameter of about 1 millimeter (mm), the lead pin elongates and contracts due to heat generated in the lead pin by the current, thereby causing a crack between the lead pin and a glass material or the like. Thus, air-tightness may not be sufficiently ensured.

In order to solve the problem due to the heat generated in the lead pin, a method is considered to lower a line resistance of the lead pin by increasing the diameter of the lead pin in which the current flows. However, hermetic sealing itself becomes difficult with an increase of the diameter of the lead pin to about 1 mm or larger. Therefore, a large current needs to flow in the lead pin having a diameter of about 1 mm at the maximum.

If an alternating current flows in the lead pin made of a magnetic material, the lead pin may vibrate due to magnetostriction of the lead pin, thereby accelerating generation of a crack between the lead pin and the glass material.

### SUMMARY OF THE INVENTION

The present invention has been made to solve the aforementioned problem, and the hermetic seal according to the present invention is constructed in such a manner as to include a package base; a glass material provided on an inside of the package base; and a lead pin that is provided to penetrate through the glass material and is composed of a copper-tungsten alloy.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a perspective view illustrating a configuration of a hermetic seal according to a first embodiment of the present invention; and

FIG. 2 is a perspective view illustrating a configuration of a package including a plurality of hermetic seals according to a second embodiment of the present invention.

### DETAILED DESCRIPTION OF THE PREFERRED EMBODIMENTS

Exemplary embodiments of a hermetic seal according to the present invention are explained in detail below with reference to the accompanying drawings. In each drawing, the same or similar components are designated by the same reference numerals.

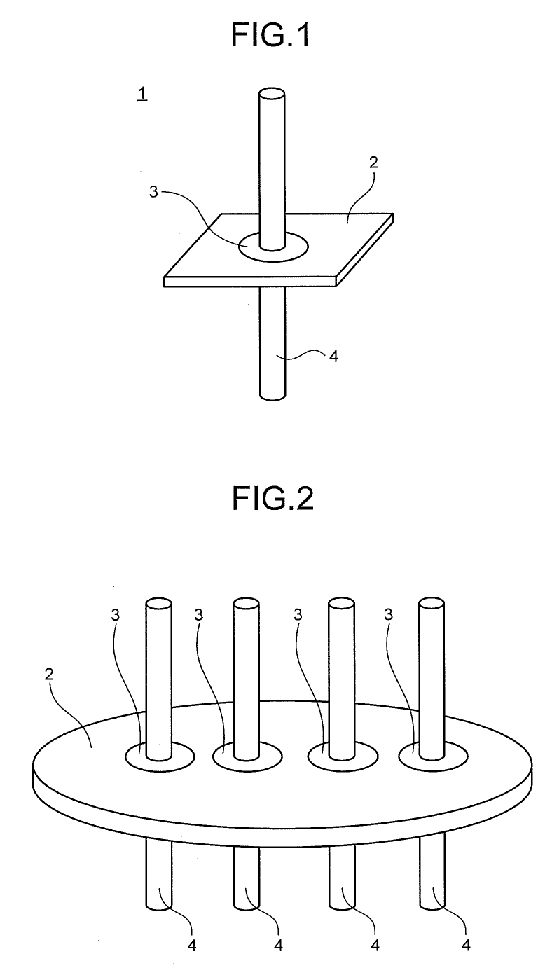

FIG. 1 is a perspective view illustrating a configuration of a hermetic seal 1 according to a first embodiment of the present invention. As shown in FIG. 1, a glass material 3 is embedded in a circular through hole formed in a package base 2, and a lead pin 4 is provided to penetrate through a central portion of the glass material 3. An iron-nickel alloy, a nickel-molybdenum alloy, or the like is used as a material of the package base 2, and a borosilicate glass or a soda glass is used as a material of the glass material 3. The lead pin 4 is composed of a copper-tungsten alloy.

The coefficient of thermal expansion of a borosilicate glass or a soda glass as a material of the glass material 3 is about 100×10⁻⁷/Kelvin (K), and an iron-nickel alloy or a nickel-molybdenum alloy as a material of the package base 2 and a copper-tungsten alloy as a material of the lead pin 4 also have a coefficient of thermal expansion of about 100×10⁻⁷/K.

A method of manufacturing the hermetic seal 1 according to the first embodiment is simply explained. First, a through hole is formed in the package base 2. Next, the lead pin 4 is arranged in the center of the through hole. Then, the components are heated to about 1000° C., which is a melting point of a glass, to weld and fix the glass material 3.

In this manner, because the components are heated to a high temperature of about 1000° C. in welding the glass material 3 in manufacturing the hermetic seal 1, a stress at normal temperature decreases as the coefficients of thermal expansion of the package base 2, the glass material 3, and the lead pin 4 become similar.

The hermetic seal 1 includes the package base 2, the glass material 3, and the lead pin 4 having similar coefficients of thermal expansion, so that an internal stress is small. Therefore, a crack is not easily generated between the glass material 3 and the lead pin 4 and between the glass material 3 and the package base 2.

The lead pin 4 of the hermetic seal 1 is composed of a copper-tungsten alloy, so that the resistivity of the lead pin 4 can be lowered to 1×10⁻⁷ Ωcm or less, which is lower than in the conventional case where the lead pin is composed of a nickel-molybdenum alloy, a nickel-chrome-molybdenum alloy, or the like. Therefore, even when a large current flows in the lead pin 4, an amount of heat generated in the lead pin 4 can be made small, enabling to obtain a hermetic seal with small amount of expansion/contraction due to heat generated in the lead pin 4 and high reliability.

According to the first embodiment, it is possible to obtain a hermetic seal with high reliability, in which the seal is hardly broken due to occurrence of a crack, for example, even if a large current of about 5 A on the average keeps flowing in the lead pin 4 having a diameter of about 1 mm.

Moreover, according to the first embodiment, because the lead pin 4 composed of a nonmagnetic material is used, the lead pin 4 does not vibrate due to magnetostriction even when an alternating current flows in the lead pin 4, so that vibration that may cause a clack between the lead pin 4 and the glass material 3 does not occur.

Particularly, when a composition of a copper-tungsten alloy used for the lead pin 4 is 30% by mass of copper, i.e., 70% by mass of tungsten, the lead pin 4 has a small resistivity and a coefficient of thermal expansion close to that of the glass material 3, enabling thus to improve reliability more effectively. The resistivity of the copper-tungsten alloy containing 30% by mass of copper is about 0.36×10⁻⁷ Ωcm. The content rate of copper does not need to be exactly 30% by mass and can be in the range of 25% or more to 35% or less by mass. The copper-tungsten alloy does not need to be composed of only copper and tungsten, but can contain other materials so long as copper and tungsten are main components.

FIG. 2 is a perspective view illustrating an example of a package including a plurality of hermetic seals according to a second embodiment of the present invention. In the case where the package includes the hermetic seals of the present invention as shown in FIG. 2, the reliability of elements packaged inside may degrade even when air-tightness of only one hermetic seal is impaired. Thus, the reliability can be improved significantly by using the hermetic seal of the present embodiment of the present invention.

According to an aspect of the present invention, it is possible to obtain a hermetic seal with high reliability in which a crack is not easily generated between a lead pin and a glass material even when a large current flows in the lead pin.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A hermetic seal comprising:
a package base;
a glass material provided on an inside of the package base; and
a lead pin that is provided to penetrate through the glass material and is composed of a copper-tungsten alloy.

2. The hermetic seal according to claim 1, wherein the lead pin is composed of the copper-tungsten alloy containing copper in a range of 25% or more to 35% or less by mass.

3. The hermetic seal according to claim 2, wherein the lead pin is composed of the copper-tungsten alloy containing 30% by mass of copper.
